(19) United States
(12) Patent Application Publication
(10) Pub. No.: US 2010/0033082 A1
(43) Pub. Date: Feb. 11, 2010

(54) Method of Manufacture of a Multi-Layer Phosphorescent Organic Light Emitting Device, and Articles Thereof

(75) Inventors: Jie Liu, Niskayuna, NY (US); Kelly Scott Chichak, Clifton Park, NY (US); Anil Raj Duggal, Niskayuna, NY (US); Qing Ye, Schenectady, NY (US)

Correspondence Address: GENERAL ELECTRIC COMPANY;GLOBAL RESEARCH, ONE RESEARCH CIRCLE, PATENT DOCKET RM. BLDG. K1-4A59, NISKAYUNA, NY, 12309, US

(73) Assignee: GENERAL ELECTRIC COMPANY, Schenectady, NY (US)

(21) Appl. No.: 12/187,749

(22) Filed: Aug. 7, 2008

(51) Int. Cl. H01L 51/52; H01J 1/63; B05D 5/12

(52) U.S. Cl. 313/504; 427/66

(57) ABSTRACT

A method for forming multi-emissive phosphorescent layers for a phosphorescent OLED comprises coating a first phosphorescent material from a first solvent onto a first electrode and removing the first solvent to form a first emissive layer; and coating a second phosphorescent material from a second solvent onto the first emissive layer and removing the second solvent to form a second emissive layer, wherein the first and second emissive layers are not cured after coating, and wherein the first emissive layer has negligible solubility in the second solvent.

### BACKGROUND OF THE INVENTION

This disclosure relates generally to a method of manufacture of multi-layer, phosphorescent organic light emitting devices, and articles thereof.

Organic light emitting devices (OLEDs) with multi-layered structures are generally preferred to achieve high performance and meet specific requirements such as white light required for illumination. Phosphorescent emissive materials in OLEDs are desirable because they can potentially achieve 100% internal quantum efficiency (IQE) relative to 25% IQE for fluorescent emissive materials.

Current state-of-the-art phosphorescent emissive materials are available as small molecules. Multi-layered phosphorescent OLEDs based on small molecules are typically produced via vacuum deposition of the organic materials, which is disadvantaged by high cost and low manufacturing throughput.

Multi-emission phosphorescent OLEDs fabricated via solvent coating such as gravure coating, screen-printing, and other solvent coating methods have not been demonstrated, although advantages are anticipated in both cost and throughput compared to vacuum deposition The greatest challenge relates to the solubility of the phosphorescent materials in most organic solvents. Solvents used to apply one phosphorescent emissive layer can partially dissolve pre-deposited underlying phosphorescent layer(s), especially when the underlying layer comprises a compound phosphorescent dye. Compound phosphorescent dyes comprise two or more chromophores linked by covalent or ionic bonds.

Therefore, an ongoing challenge exists in making low cost, efficient phosphorescent OLEDs comprising multiple emissive layers (e.g. a red, green, blue (RGB) applied to a substrate from a solvent.

### BRIEF SUMMARY OF THE INVENTION

In one embodiment, a method for forming multi-emissive phosphorescent layers for a phosphorescent OLED comprises coating a first phosphorescent material from a first solvent onto a first electrode and removing the first solvent to form a first emissive layer; and coating a second phosphorescent material from a second solvent onto the first emissive layer and removing the second solvent to form a second emissive layer, wherein the first and second emissive layers are not cured after coating, and wherein the first emissive layer has negligible solubility in the second solvent.

Also disclosed is the multi-emissive phosphorescent OLED device formed by the described method.

In another embodiment, a multi-emissive phosphorescent OLED device comprises a substrate; an anode layer disposed on the substrate; a first emissive layer disposed on the anode layer, wherein the first emissive layer comprises a first polymeric phosphorescent material; a second emissive layer disposed on the first emissive layer, wherein the second emissive layer comprises a second phosphorescent material, wherein the first and second emissive layers are not cured; and a cathode layer disposed on the second emissive layer.

In still another embodiment, an article comprises the disclosed phosphorescent OLED, wherein the article is for a lighting application.

### BRIEF DESCRIPTION OF DRAWINGS

In the drawings, like elements are numbered alike.

FIG. 1 is a cross-section of a phosphorescent OLED comprising two emissive layers;

FIG. 2 is a cross-section of a phosphorescent OLED comprising two emissive layers and a hole-injection layer;

FIG. 3 is a cross-section of a phosphorescent OLED comprising two emissive layers and an electron-injection layer;

FIG. 4 is a cross-section of a phosphorescent OLED comprising two emissive layers, a hole-injection layer, and an electron-injection layer.

FIG. 5 is a cross-section of a phosphorescent OLED comprising three emissive layers, a hole-injection layer, and an electron-injection layer.

FIG. 6 is a graph of the electroluminescence spectrum of the phosphorescent OLED device prepared in the Example.

### DETAILED DESCRIPTION OF THE INVENTION

A method is disclosed for preparing a multi-emission phosphorescent organic light emitting device (OLED) comprising at least two discrete organic phosphorescent emissive layers. Each emissive layer is coated from a solvent, followed by removal of the solvent before applying the next layer. The coating process relies on the differential solubility properties of the dried, as-coated emissive layers rather than on a post-coating chemical change such as chemical crosslinking (“curing”). The OLED device can be produced at potentially higher throughput and lower cost compared to devices having emissive layers formed by vacuum evaporation methods or by other coating methods that require a post-coating curing step for the emissive layers. The solvent can be water and/or an organic solvent. Coating mixtures can be in the form of solutions, solid-liquid dispersions, and liquid-liquid dispersions. The coating process can be performed at any temperature providing the emissive properties of the coated layers are not adversely affected.

The emissive layers comprise phosphorescent materials that emit light from triplet states (“phosphorescence”) or intermediate non-triplet states, at ambient temperature, as opposed to fluorescent materials that emit from singlet states (“fluorescence”). Phosphorescence generally occurs in a time frame exceeding at least 10 nanoseconds, and typically greater than 100 nanoseconds. If the radiative lifetime of phosphorescence is too long, triplets can decay by a thermal (non-radiative) mechanism. Non-radiative decay mechanisms are typically temperature dependent, such that an organic material which phosphoresces at liquid nitrogen temperatures typically does not phosphoresce at ambient temperature.

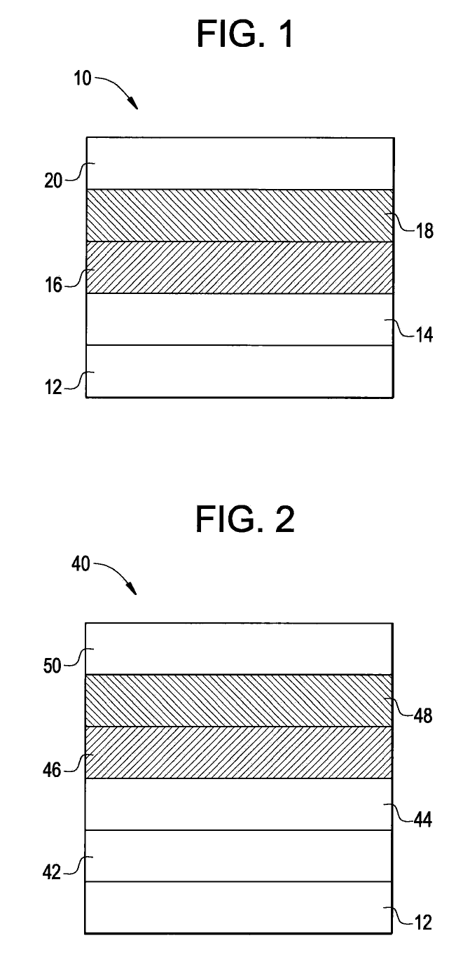

FIG. 1 is a schematic cross-section of a phosphorescent OLED 10 comprising a substrate 12, a first electrode 14 disposed on the substrate 12, a first emissive layer 16 disposed on first electrode 14 comprising a first phosphorescent material, a second emissive layer 18 disposed on the first emissive layer 16 comprising a second phosphorescent material, and a second electrode 20 disposed on the second emissive layer 18.

The process of preparing the phosphorescent OLED comprises coating a first mixture comprising the first phosphorescent material and a first solvent onto a support surface (e.g., one of the component layers that define the phosphorescent OLED such as the electrode, for example), and removing the first solvent to form a first emissive layer 16; and coating a second mixture comprising the second phosphorescent material and a second solvent on the first emissive layer, and removing the second solvent to form the second emissive layer 18. In the embodiment of FIG. 1, the first emissive layer 16 is coated on the first electrode layer 14, e.g., the anode. The first emissive layer has negligible solubility in the second solvent, and the first and second emissive layers are not cured after coating. The term “negligible solubility” means the emissive layers remain discrete after coating and the boundary between the two emissive layers can be readily discerned in cross-section photomicrographs.

The phosphorescent OLED 10 may further include a hole-injection layer, a hole-transporting layer, a hole-blocking layer, an electron-injection layer, an electron-transporting layer, an electron-blocking layer, and the like, as described in more detail below.

The phosphorescent material can be polymeric or non-polymeric, and emits in the visible wavelength region of the electromagnetic spectrum (400 nanometers to 700 nanometer wavelength). Non-polymeric organic phosphorescent materials (herein referred to as phosphorescent dyes) include molecular and compound organic phosphorescent dyes. A compound phosphorescent dye has two chromophores having different phosphorescent emission characteristics. A phosphorescent chromophore consists of the functional groups and bonds that contribute to the phosphorescence of the material.

A phosphorescent chromophore can comprise inorganic, organic or organometallic chemical groups. Polymeric organic phosphorescent materials (also referred to as phosphorescent polymers) are organic polymers comprising a phosphorescent chromophore bound covalently to the polymer via a chemical linking group, or alternatively, comprising a phosphorescent dye ionically bound to the organic polymer in the form a salt.

The emissive layers can comprise a host material. Generally, a host material is an electroactive organic material having electron-transporting and/or hole-transporting properties suitable for a phosphorescent emissive layer. Host materials can also have emissive characteristics, but their primary function is for transporting holes and/or electrons and acting as a vehicle for the solvent mixture comprising the phosphorescent material. Likewise, a phosphorescent material can also have hole- or electron-transporting capabilities, but the primary function of the phosphorescent material is emissive. Those skilled in the art will recognize that balancing the emissive and electron/hole-transporting properties of host and phosphorescent materials is necessary to provide optimum performance of the emissive layers.

An organic phosphorescent emissive layer generally comprises at least one organic material. The organic material can be emissive or non-emissive, and it can be polymeric or non-polymeric. The term “organic” is understood to mean having at least one carbon-carbon and at least one carbon-hydrogen bond. An organic phosphorescent emissive layer can comprise inorganic or organic phosphorescent materials suspended in an organic polymer matrix, organic phosphorescent dyes suspended in an inorganic host material; and organic phosphorescent polymers comprising inorganic, organic and organometallic phosphorescent chromophores covalently or ionically bound to an organic polymer.

When a current is applied, the electrode layer acting as the anode layer injects holes into the emissive layers, and the electrode layer acting as the cathode layer injects electrons into the emissive layers. The injected holes and electrons each migrate toward the oppositely charged electrode. When an electron and hole localize on the same phosphorescent material in an emissive layer, an “exciton,” or electron-hole pair having an excited energy state, is formed. Light is emitted when the exciton relaxes via a photoemissive mechanism. Non-radiative mechanisms, such as thermal relaxation, can also occur.

Polymeric and/or non-polymeric phosphorescent materials and host materials can be employed in adjacent layers providing each emissive layer is coated from solvent and the already coated emissive layers have negligible solubility in the solvent of succeeding emissive layers. In one embodiment, the first emissive layer comprises an organic phosphorescent polymer and the second emissive layer comprises a non-polymeric phosphorescent material and a polymeric host material. The first and/or second emissive layer can further comprise a mixture of phosphorescent materials. The order of the emissive layers is not restricted providing the emissive properties of the layers are not adversely affected.

Either electrode can be the cathode or anode providing the OLED performance remains robust. Typically, the first electrode layer nearest the substrate is the anode layer, and the second electrode layer farthest from the substrate is the cathode layer. In one embodiment, the first electrode layer is the cathode layer, and the second electrode layer is the anode layer. Hole-injecting and hole-transporting layers, when used, are placed most advantageously near or adjacent to the anode layer. Likewise, electron-injection and electron-transporting layers, when used, are positioned near or adjacent to the cathode layers.

In typical phosphorescent light emitting devices, phosphorescent dyes are usually presented as a minor dopant material dispersed in a host material. In order to maintain high photoluminescence (PL) quantum efficiency of a phosphorescent dye, the corresponding host material should possess a triplet energy gap no smaller than that of the dye to prevent energy back transfer (a loss of PL quantum efficiency) from dye to the host and/or any impurities in contact with the dye. A secondary function of the host material is to serve as a vehicle for suspending or otherwise stabilizing the mixture of a solvent and a phosphorescent material in the process of coating an emissive layer.

Triplet quenching experiments are conducted to evaluate whether or not the energy gap of a host material is large enough (and/or the material is pure enough) to prevent energy back transfer from a phosphorescent dye dispersed in the host material. For this purpose, insulating materials containing wide bandgaps, such as polystyrene (PS), are usually used as a reference. A dye dispersed in PS reflects its intrinsic photophysical properties such as PL quantum efficiency and a characteristic phosphorescent lifetime observed in diluted solutions. Time-resolved PL measurements record phosphorescent intensity over time; and comparison of such phosphorescent decay profiles of a dye dispersed in the host material of interest relative to in PS provides direct information whether energy back transfer occurs.

The phosphorescent emissive layers can comprise at least one electroactive host material. Electroactive materials are organic materials which are susceptible to charge conduction when subjected to a voltage bias, for example organic materials which conduct electrons and/or holes in an organic light emitting device (OLED). Electroactive materials include, for example, organic semiconducting polymers. Those skilled in the art will appreciate that while electroluminescent materials represent a class of electroactive materials, a material need not be electroluminescent to be electroactive. Electroactive host materials include polymeric, non-polymeric, electroluminescent and otherwise electroactive materials. Exemplary non-polymeric host materials are listed in Table 1 together with their Chemical Abstracts Registry Number (CAS No.).

TABLE 1
Exemplary Non-Polymeric Host Materials

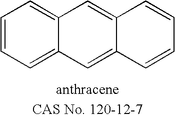

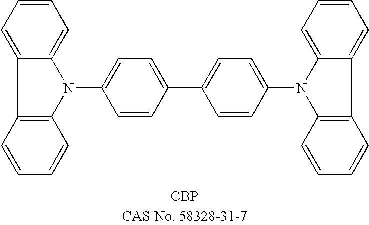

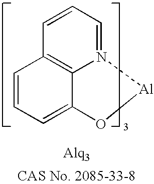

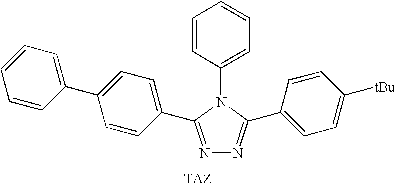

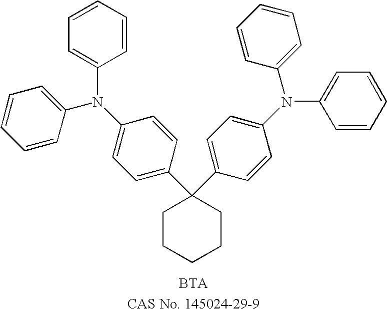

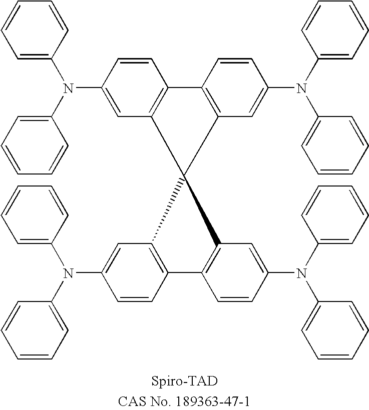

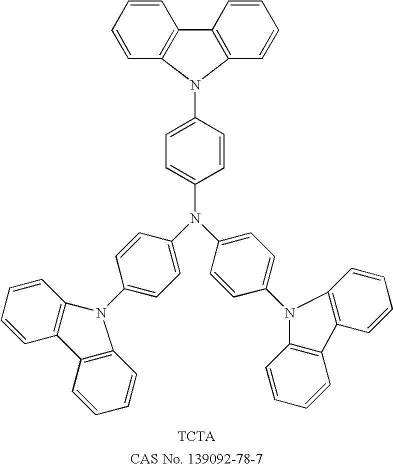

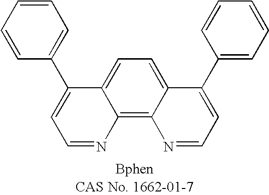

Alternatively, the host material can be an electroactive polymeric material, examples of which include polyvinylcarbazole (PVK), polyphenylenevinylene (PPV), phenyl-substituted polyphenylenevinylene (PhPPV), poly(9,9-dioctyl fluorene), and the like. In one embodiment, the phosphorescent emissive layer comprises a polymeric host material comprising a blue light emitting electroluminescent organic material, for example, poly(9,9-dioctyl fluorene).

In general, it is desirable that the phosphorescent material of the emissive layer be characterized by a lowest accessible triplet state energy T1, which is less than the lowest accessible triplet state energy T2 of the electroactive host material. As will be appreciated by those skilled in the art, energy transfer from the electroactive host material to the phosphorescent material of the emissive layer can be especially favorable under circumstances where T1 is less than T2.

The host material can be present, based on total weight of the emissive layer, in amounts ranging from 1 to 99 wt % (weight percent), more specifically 50 to 98 wt %, and even more specifically 75 to 95 wt % of the emissive layer. The host materials can be present in combination providing the emissive and solubility properties of the emissive layer are not adversely affected.

The polymeric host material can have a number average molecular weight (Mₙ) greater than 2,000 grams per mole, greater than 5000 grams per mole, greater than 15,000 grams per mole, and still more specifically greater than about 25,000 grams per mole as determined by gel permeation chromatography. Those skilled in the art will appreciate that number average molecular weight of polymeric materials may also be determined by other techniques such as ¹H-NMR spectroscopy.

Exemplary polymeric host materials include bisphenol-A polycarbonate, a polymer blend comprising a bisphenol-A polycarbonate, a bisphenol-A copolycarbonate, a blend comprising a bisphenol-A copolycarbonate, or like polymeric materials. Other polymeric host materials include vinyl polymers such as polyvinyl chloride, polystyrene, poly(methyl methacrylate), poly(methyl acrylate), polymerized polyacrylates such as Sartomer 454, and the like; acetal polymers; polyesters such as poly(ethylene terephthalate); polyamides such as nylon 6; polyimides; polyetherimides such as ULTEM; polyethertherketones; polysulfones; polyethersulfones such as RADEL and UDEL, and the like. The polymeric host material can be homopolymer, a random copolymer, a block copolymer, a terpolymer, a graft-copolymer, an alternating copolymer, or like polymeric material. Polymeric blends useful as the polymeric host material can be prepared using standard techniques known in the art, for example extrusion blending.

The polymeric host material can comprise an electroactive polymer. Electroactive polymers include, for example, organic semiconducting polymers. Those skilled in the art will appreciate that while electroluminescent polymers represent a class of electroactive polymers, a material need not be electroluminescent to be electroactive. Electroactive polymers generally possess a delocalized π-electron system, which typically enables the polymer chains to support positive charge carriers (holes) and negative charge carriers (electrons) with relatively high mobility. Exemplary electroactive polymers are illustrated by poly(n-vinylcarbazole) (“PVK”, emitting violet-to-blue light in a wavelength range of from about 380 to about 500 nanometers) and poly(n-vinylcarbazole) derivatives; polyfluorene and polyfluorene derivatives such as poly(dialkyl fluorene), for example poly(9,9-dihexyl fluorene) (emitting light in a wavelength range of from about 410 to about 550 nanometers), poly(dioctyl fluorene) (wavelength at peak electroluminescent (EL) emission of about 436 nanometers), and poly{9,9-bis(3,6-dioxaheptyl)-fluorene-2,7-diyl} (emitting light in a wavelength range of from about 410 to about 550 nanometers); poly(paraphenylene) (“PPP”) and its derivatives such as poly(2-decyloxy-1,4-phenylene) (emitting light in a wavelength range of from about 400 to about 550 nanometers) and poly(2,5-diheptyl-1,4-phenylene); poly(p-phenylene vinylene) (“PPV”) and its derivatives such as dialkoxy-substituted PPV and cyano-substituted PPV; polythiophene and its derivatives such as poly(3-alkylthiophene), poly(4,4′-dialkyl-2,2′-bithiophene), and poly(2,5-thienylene vinylene); poly(pyridine vinylene) and its derivatives; polyquinoxaline and its derivatives; and polyquinoline and its derivatives. Mixtures of these polymers and/or copolymers comprising structural units common to two or more of the aforementioned polymers can be used as the polymeric component.

Additionally, the electroactive polymer host material can comprise a polysilane. Typically, polysilanes are linear silicon-backbone polymers substituted with a variety of alkyl and/or aryl groups. Polysilanes are quasi one-dimensional materials with delocalized sigma-conjugated electrons along polymer backbone. Examples of suitable polysilanes include, but are not limited to, poly(di-n-butylsilane), poly(di-n-pentylsilane), poly(di-n-hexylsilane), poly(methylphenylsilane), and poly{bis(p-butylphenyl)silane}. The polysilanes generally emit light in a wavelength in a range from about 320 nanometers to about 420 nanometers.

Further disclosed is a phosphorescent OLED device 40 shown schematically in FIG. 2 comprising substrate 12, an anode layer 42 disposed on the substrate layer 12, a hole-injection layer (HIL) 44 disposed on the first electrode layer 42, a first emissive layer 46 disposed on the hole-injection layer 44, a second emissive layer 48 disposed on the first emissive layer 46, and a cathode layer 50 disposed on the second emissive layer 48. The first emissive layer 46 is formed by coating a first mixture comprising a first phosphorescent material from a first solvent, and removing the first solvent to form the first emissive layer 46; and the second emissive layer 48 is formed by coating a second mixture comprising a second phosphorescent material from a second solvent on the first emissive layer 46, and removing the second solvent to form the second emissive layer 48. The first and second emissive layers are not cured after coating, and the first emissive layer has negligible solubility in the second solvent. Each emissive layer can comprise a phosphorescent dye, a phosphorescent polymer, a host material, mixtures of phosphorescent materials, or a combination of the foregoing. A hole-transporting host material is most advantageously employed in the first emissive layer nearest the anode, and an electron-transporting host material is most advantageously employed in the second emissive layer nearest the cathode. In one embodiment, the cathode is a bi-layer comprising a NaF layer disposed on the second emissive layer, and an aluminum layer disposed on the NaF layer.

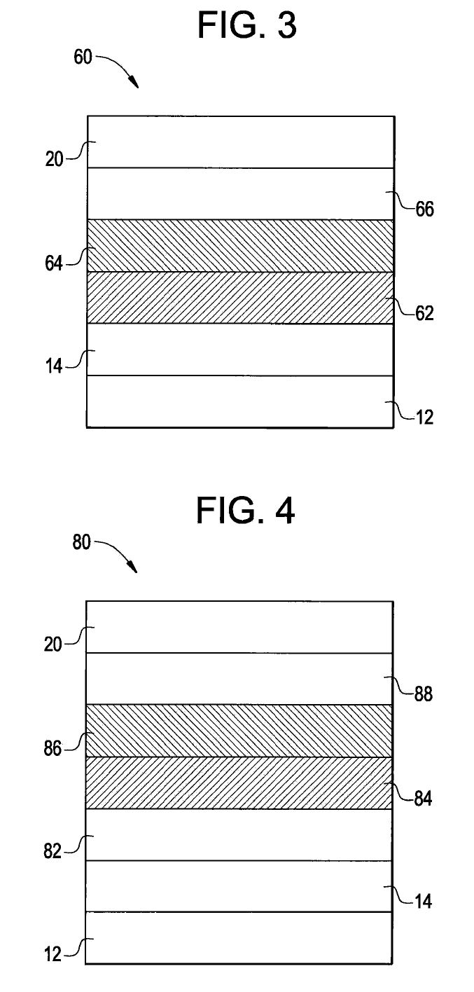

The phosphorescent OLED can further comprise an electron-injection layer (EIL). This is shown schematically in FIG. 3 of phosphorescent OLED 60, wherein electron-injection layer 66 is most advantageously disposed between and in contact with a second electrode layer 20 (cathode), and a second phosphorescent emissive layer 64. Also shown are first phosphorescent emissive layer 62, first electrode layer 14 (anode), and substrate 12. As described above, the first phosphorescent emissive layer is coated from a first solvent and the second phosphorescent emissive layer is coated from a second solvent, and neither emissive layer is cured after coating. The first emissive layer has negligible solubility in the second solvent, and neither emissive layer is cured after coating. Each emissive layer can comprise a phosphorescent dye, a phosphorescent polymer, a host material, mixtures of phosphorescent materials, or a combination of the foregoing. As described above, a hole-transporting host material is most advantageously employed in the first emissive layer nearest the anode, and an electron-transporting host material is most advantageously employed in the second emissive layer nearest the cathode.

In still another embodiment depicted schematically in FIG. 4, phosphorescent OLED 80 comprises a hole-injection layer 82 and an electron-injection layer 88. Hole-injection layer 82 is disposed between and in contact with a first electrode layer 14 (anode) and a first organic phosphorescent emissive layer 84. The electron-injection layer 88 is disposed between and in contact with the second electrode layer 20 (cathode) and the second organic phosphorescent emissive layer 86. Also shown are first electrode layer 14 (anode) and substrate 12. As described above, the first phosphorescent emissive layer is coated from a first solvent and the second phosphorescent emissive layer is coated from a second solvent, and neither emissive layer is cured after coating. The first emissive layer has negligible solubility in the second solvent, and neither emissive layer is cured after coating. Each emissive layer can comprise a phosphorescent dye, a phosphorescent polymer, a host material, mixtures of phosphorescent materials, or a combination of the foregoing. As described above, a hole-transporting host material is most advantageously employed in the first emissive layer nearest the anode, and an electron-transporting host material is most advantageously employed in the second emissive layer nearest the cathode.

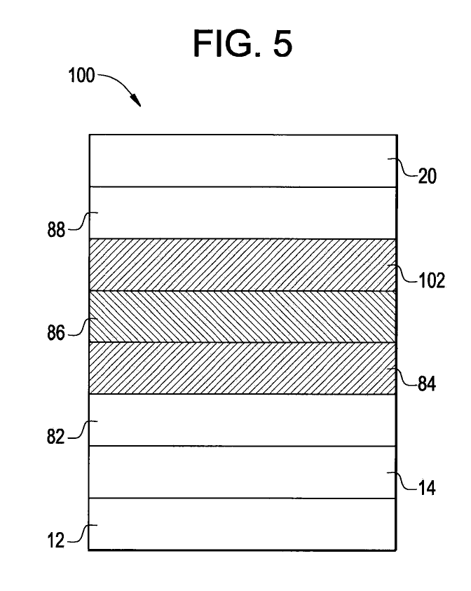

The disclosed process can further comprise coating a third phosphorescent material from a third solvent on the second emissive layer, and removing the third solvent to form a third emissive layer disposed on the second emissive layer; wherein the second phosphorescent material and the first phosphorescent material have negligible solubility in the third solvent. A phosphorescent OLED device 100 having three emissive layers is schematically shown in FIG. 5, wherein a third emissive layer (102) is disposed between and in contact with a second emissive layer 86 and an electron-injection layer 88. Hole-injection layer 82 is disposed between and in contact with a first electrode layer 14 (anode) and a first emissive layer 84. The electron-injection layer 88 is disposed between and in contact with the second electrode layer 20 (cathode) and the third organic phosphorescent emissive layer 102. Also shown are first electrode layer 14 (anode) and substrate 12. As described above, the third phosphorescent emissive layer is coated from a third solvent and the second phosphorescent emissive layer is coated from a second solvent, and neither emissive layer is cured after coating. The first and second emissive layers have negligible solubility in the third solvent, and none of the emissive layers are cured after coating. Each emissive layer can comprise a phosphorescent dye, a phosphorescent polymer, a host material, mixtures of phosphorescent materials, or a combination of the foregoing. As described above, a hole-transporting host material is most advantageously employed in the first emissive layer nearest the anode, and an electron-transporting host material is most advantageously employed in the third emissive layer nearest the cathode.

Those skilled in the art will recognize that the phosphorescent OLED can further comprise an electron-transporting layer (ETL, not shown), and/or a hole-blocking layer (HBL, not shown) disposed between a cathode layer and an emissive layer, and/or a hole-transporting layer (HTL, not shown) and/or electron-blocking layer (EBL, not shown) disposed between the anode layer and an emissive layer. These layers can be constructed by means and materials well known in the art. No restriction is placed on the number or combination of the above described layers providing the emissive properties of the phosphorescent OLED device and the layer integrity of the emissive layers are not adversely affected.

The substrate can be flexible or rigid and can comprise transparent, translucent or opaque materials, including plastic, metal foil, and glass. The substrate can further comprise a semiconductor material such as silicon in order to facilitate the fabrication of circuitry. The material and thickness of the substrate are chosen based on the desired structural, conductive, and optical properties, but is otherwise not restricted.

The anode layer can comprise any material that is sufficiently conductive to transport holes to the emissive layers and has a work function higher than about 4 eV (electron volts). Exemplary anode materials include conductive metal oxides, such as indium tin oxide (ITO) and indium zinc oxide (IZO), aluminum zinc oxide (AlZnO), and metals. The anode and the substrate can be sufficiently transparent to create a bottom-emitting device. In particular, the anode comprises transparent commercially available ITO (anode) deposited on a transparent substrate such as glass or plastic (substrate). The anode can also be opaque and/or reflective. A reflective anode can be preferred for some top-emitting devices, to increase the amount of light emitted from the top of the device. The material and thickness of the anode is chosen based on the desired conductive and optical properties.

Exemplary materials for hole-injection layers (HIL) include polyfluorocarbohydride, porphyrin, or p-doped amino derivatives. Exemplary porphyrins include metallophthalocyanines, particularly copper phthalocyanine. Another family of HIL materials is p-doped conducting polymer which include poly(3,4-ethylendioxythiophene) (PEDOT) or polyaniline (PANi) heavily p-doped with polyacids such as polystyrene sulfonic acid (PSSA). The HIL can have a thickness from 50 to 2000 angstroms, more particularly 200 to 1000 angstroms, and even more particularly 400 to 700 angstroms.

Exemplary materials for hole-transporting layers (HTL) include polymers comprising structural units derived from amines selected from the group consisting of N,N′-bis(1-naphyl)-N,N′-diphenyl-1,1′-biphenyl-4,4′-diamine (NPB), N,N′-diphenyl-N,N′-bis(3-methlphenyl)-(1,1′-biphenyl)-4,4′-diamine (TPD), 2T-NATA, derivatives of the foregoing amines, and combinations including at least one of the foregoing amines.

Exemplary materials for electron-injection layers (EIL) include alkali metals, alkaline earth metals, alkali metal halides, alkaline earth metal halides, alkali metal oxide, or metal carbonate. More specifically, the EIL can comprise Li, K, Cs, Ca, Ba, LiF, CsF, NaF, CaF₂, Li₂O, Cs₂O, Na₂O, Li₂CO₃, Cs₂CO₃, or Na₂CO₃.

In one embodiment each emissive layer comprises a host material capable of transporting electrons and/or holes, doped with a phosphorescent material that can trap electrons, holes, and/or excitons, such that excitons relax via a photoemissive mechanism. In one embodiment, each emissive layer comprises a single material that combines transport and emissive properties, such as for example a phosphorescent polymer having electron-transporting properties. Whether the emissive material is a dopant or a major constituent, the emissive layers can comprise other materials, such as dopants that tune the emission of the phosphorescent material. The emissive layers can also comprise a combination of phosphorescent and fluorescent materials capable of, in combination, emitting a desired spectrum of light.

The phosphorescent material can be incorporated into a polymer by doping a phosphorescent molecule into a polymer either as a separate and distinct molecular species bound by ionic association; or by incorporating the small molecule into the backbone of the polymer, so as to form a co-polymer; or by bonding the small molecule as a pendant group on the polymer. Other phosphorescent materials and structures can be used. For example, a small molecule phosphorescent material can be present as the core of a dendrimer.

Many useful phosphorescent materials include one or more ligands bound to a metal center. A ligand is referred to as “photoactive” if it contributes directly to the photoactive properties of an emissive material. A “photoactive” ligand can provide, in conjunction with a metal, the energy levels from which and to which an electron moves when a photon is emitted. Other ligands are referred to as “ancillary.” Ancillary ligands modify the photoactive properties of the molecule, for example by shifting the energy levels of a photoactive ligand, but ancillary ligands do not directly provide the energy levels involved in light emission. A ligand that is photoactive in one molecule can be ancillary in another. The term “emissive chromophore” refers to that portion of the chemical structure of the monomeric or polymeric phosphorescent material associated with phosphorescent dye properties. Thus, two molecules or polymers can differ in overall chemical structure while still comprising the same or essentially the same emissive chromophore. One example is shown below with the structures of FIrpic, (3), and acryloyl-FIrpic, (4).

In one embodiment, the phosphorescent materials of the emissive layers are organometallic compounds. Exemplary organometallic compounds include those that contain iridium complexes, platinum complexes, osmium complexes, ruthenium complexes, and cyclo-metallated iridium compounds such as FIrpic (bis(3,5-difluoro-2-(2-pyridyl)phenyl-(2-carboxypyridyl)iridium III) having the formula (3):

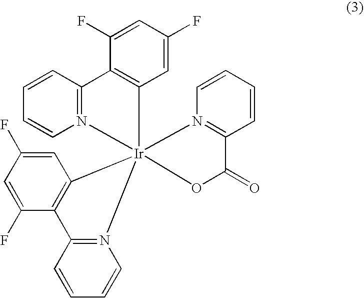

which can be substituted with one or more vinyl groups, one or more phenol groups, one or more allyl groups, or one or more acryloyl groups as shown in formula (4).

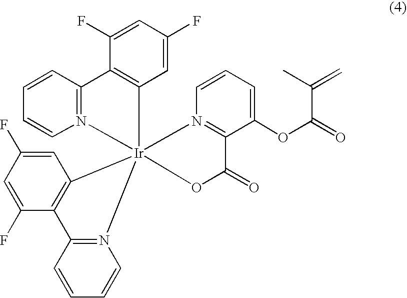

Ir(PPy)3 (tris-2-phenylpyridine iridium(III)) is another well known phosphorescent material.

Still other phosphorescent materials include polymeric and polymerizable dyes, for example blue phosphorescent dyes having the formula Ir(RPPy)₂QR′₃X and represented by the formula (4):

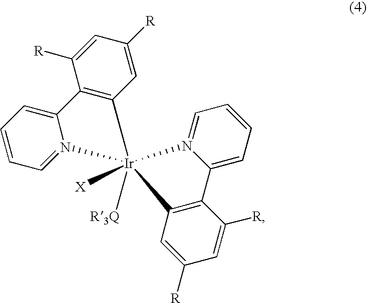

wherein X is selected from the group consisting of a halogen, —CN, —CNS, —OCN, —SCN, a thiosulfate, a sulfonyl halide, an azide or combinations thereof; R is selected from the group consisting of hydrogen, fluorine, or carbon trifluoride; Q is selected from the group consisting of nitrogen, phosphorous, arsenic, antimony or bismuth; R′ is selected from the group consisting of an alkyl group, an alkoxy group, aryl group, aryloxy group, or combinations thereof.

The term “alkyl” as used herein is intended to designate linear alkyl, branched alkyl, aralkyl, cycloalkyl, bicycloalkyl, tricycloalkyl and polycycloalkyl radicals comprising carbon and hydrogen atoms, and optionally containing atoms in addition to carbon and hydrogen. Alkyl groups can be saturated or unsaturated and can comprise, for example, vinyl or allyl.

As used herein the term “aliphatic radical” refers to an organic radical having a valence of at least one consisting of a linear or branched array of atoms that are not cyclic. Aliphatic radicals are defined to comprise at least one carbon atom The array of atoms comprising the aliphatic radical can include heteroatoms such as nitrogen, sulfur, silicon, selenium and oxygen or can be composed exclusively of carbon and hydrogen. For convenience, the term “aliphatic radical” is defined herein to encompass, as part of the “linear or branched array of atoms which is not cyclic” a wide range of functional groups such as alkyl groups, alkenyl groups, alkynyl groups, haloalkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. As an example, the 4-methylpent-1-yl radical is a C₆ aliphatic radical comprising a methyl group, the methyl group being a functional group which is an alkyl group. Similarly, the 4-nitrobut-1-yl group is a C₄ aliphatic radical comprising a nitro group, the nitro group being a functional group. An aliphatic radical can be a haloalkyl group which comprises one or more halogen atoms which can be the same or different. Halogen atoms include, for example; fluorine, chlorine, bromine, and iodine. Aliphatic radicals comprising one or more halogen atoms include the alkyl halides trifluoromethyl, bromodifluoromethyl, chlorodifluoromethyl, hexafluoroisopropylidene, chloromethyl, difluorovinylidene, trichloromethyl, bromodichloromethyl, bromoethyl, 2-bromotrimethylene (e.g. CH₂CHBrCH₂—), and the like. Further examples of aliphatic radicals include allyl, aminocarbonyl (i.e., —CONH₂), carbonyl, 2,2-dicyanoisopropylidene (i.e., —CH₂C(CN)₂CH₂—), methyl (i.e., —CH₃), methylene (i.e., —CH₂—), ethyl, ethylene, formyl (i.e. —CHO), hexyl, hexamethylene, hydroxymethyl (i.e. —CH₂OH), mercaptomethyl (i.e., —CH₂SH), methylthio (i.e., —SCH₃), methylthiomethyl (i.e., —CH 2SCH3), methoxy, methoxycarbonyl (i.e., CH₃OCO—), nitromethyl (i.e., —CH₂NO₂), thiocarbonyl, trimethylsilyl ( i.e.(CH₃)₃Si—), t-butyldimethylsilyl, 3-trimethyoxysilypropyl (i.e., (CH₃O)₃SiCH₂CH₂CH₂—), vinyl, vinylidene, and the like. By way of further example, a C₁-C₁₀ aliphatic radical contains at least one but no more than 10 carbon atoms. A methyl group (i.e., CH₃—) is an example of a C₁ aliphatic radical. A decyl group (i.e., CH₃(CH₂)₉—) is an example of a C₁₀ aliphatic radical.

As used herein the term “cycloaliphatic radical” refers to a radical having a valence of at least one, and comprising an array of atoms which is cyclic but which is not aromatic. As defined herein a “cycloahphatic radical” does not contain an aromatic group. A “cycloaliphatic radical” can comprise one or more noncyclic components.

For example, a cyclohexylmethyl group (C₆H₁₁CH₂—) is an cycloaliphatic radical which comprises a cyclohexyl ring (the array of atoms which is cyclic but which is not aromatic) and a methylene group (the noncyclic component). The cycloaliphatic radical can include heteroatoms such as nitrogen, sulfur, selenium silicon and oxygen, or can be composed exclusively of carbon and hydrogen. For convenience, the term “cycloaliphatic radical” is defined herein to encompass a wide range of functional groups such as alkyl groups, alkenyl groups, alkynyl groups, haloalkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylcyclopent-1-yl radical is a C₆ cycloaliphatic radical comprising a methyl group, the methyl group being a functional group which is an alkyl group. Similarly, the 2-nitrocyclobut-1-yl radical is a C₄ cycloaliphatic radical comprising a nitro group, the nitro group being a functional group. A cycloaliphatic radical can comprise one or more halogen atoms which can be the same or different. Halogen atoms include, for example; fluorine, chlorine, bromine, and iodine. Cycloaliphatic radicals comprising one or more halogen atoms include 2-trifluoromethylcyclohex-1-yl, 4-bromodifluoromethylcyclooct-1-yl, 2-chlorodifluoromethylcyclohex-1-yl, hexafluoroisopropylidene-2,2-bis(cyclohex-4-yl) (i.e., —C₆H₁₀C(CF₃)CeH₁₀—), 2-chloromethylcyclohex-1-yl, 3-difluoromethylenecyclohex-1-yl, 4-trichloromethylcyclohex-1-yloxy, 4-bromodichloromethylcyclohex-1-ylthio, 2-bromoethylcyclopent-1-yl, 2-bromopropylcyclohex-1-yloxy (e.g. CH₃CHBrCH₂C₆H₁₀—), and the like. Further examples of cycloaliphatic radicals include 4-allyloxycyclohex-1-yl, 4-aminocyclohex-1-yl (i.e., H₂NC₆H₁₀—), 4-aminocarbonylcyclopent-1-yl (i.e., NH₂COC₅H₈—), 4-acetyloxycyclohex-1-yl, 2,2-dicyanoisopropylidenebis(cyclohex-4-yloxy) (i.e., —OC₆H₁₀C(CN)₂C₆H₁₀O—), 3-methylcyclohex-1-yl, methylenebis(cyclohex-4-yloxy) (i.e., —OC₆H₁₀CH₂C₆H₁₀O—), 1-ethylcyclobut-1-yl, cyclopropylethenyl, 3-formyl-2-terahydrofuranyl, 2-hexyl-5-tetrahydrofuranyl, hexamethylene-1,6-bis(cyclohex-4-yloxy) (i.e., —OC₆H₁₀CH₂C₆H₁₀O), 4-hydroxymethylcyclohex-1-yl (i.e., 4-HOCH₂C₆H₁₀O—), 4-mercaptomethylcyclohex-1-yl (i.e., 4-HSCH₂C₆H₁₀—), 4-methylthiocyclohex-1-yl (i.e., 4-CH₃SC₆H₁₀—), 4-methoxycyclohex-1-yl, 2-methoxycarbonylcyclohex-1-yloxy (2-CH₃OCOC₆H₁₀O—), 4-nitromethylcyclohex-1-yl (i.e., NO₂CH₂C₆H₁₀—), 3-trimethylsilylcyclohex-1-yl, 2-t-butyldimethylsilylcyclopent-1-yl, 4-trimethoxysilylethylcyclohex-1-yl (e.g. (CH₃O)₃SiCH₂CH₂C₆H₁₀—), 4-vinylcyclohexen-1-yl, vinylidenebis(cyclohexyl), and the like. The term “a C₃-C₁₀ cycloaliphatic radical” includes cycloaliphatic radicals containing at least three but no more than 10 carbon atoms. The cycloaliphatic radical 2-tetrahydrofuranyl (C₄H₇O—) represents a C₄ cycloaliphatic radical. The cyclohexylmethyl radical (C₆H₁₁CH₂—) represents a C₇ cycloaliphatic radical.

In a more specific embodiment, the phosphorescent material is selected from the group consisting of bis(2-(9,9-dihexylfluorenyl)-1-pyridine) (acetylacetonate)iridium(III), sold as ADS078GE by American Dye Source Inc., formula (5):

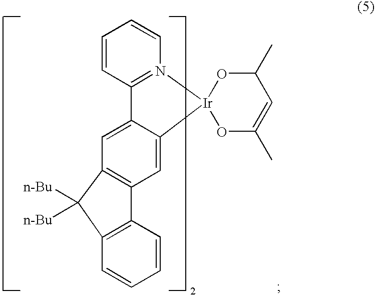

1,3-bis[(p-tert-butyl)phenyl-1,3,4-oxadiazoyl]benzene, OXD-7, from H. W. Sands, formula (6):

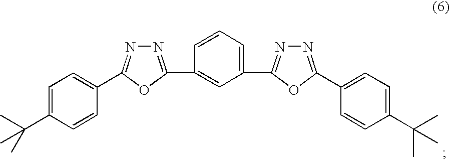

red emitting dimer, ADS067RE, formula (7):

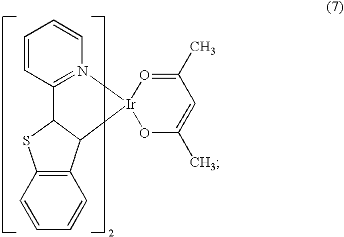

red emitting ADS069RE by American Dye Source Inc., formula (8):

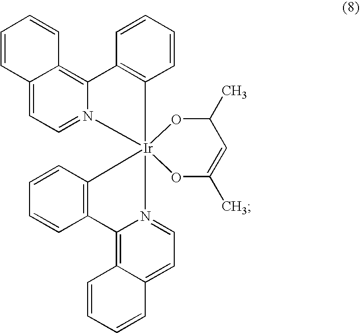

blue emitting phosphorescent polymeric dye 275-44-5, formula (9)

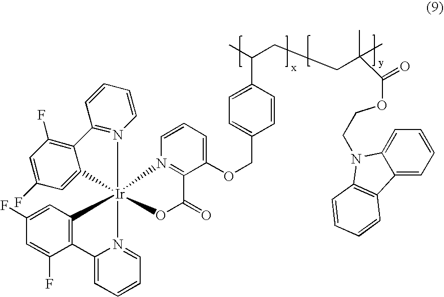

wherein x and y are integers greater than 1;
tris[2-(2-pyridinyl)phenyl-C,N]-iridium, (Ir(ppy)3); tris-(phenylpyridine)iridium(III); poly(STPPB_Irppy); poly(carbazole_F(Ir)pic); and combinations thereof. In general, organic phosphorescent dyes such as FIrpic have higher photoluminescence quantum efficiency in diluted solutions compared to solid state films because of self-quenching in the solid-state films.

The phosphorescent OLED can further comprise a non-polymeric electron-transport material as a component of one of the previously described layers or as a separate layer. The electron-transport material can be intrinsic (undoped), or doped. Doping can be used to enhance conductivity. Alq3 (aluminum tris(8-hydroxyquinoline)) is an example of a non-polymeric intrinsic electron-transport material. An example of an n-doped electron-transport material is BPhen (4,7-diphenyl-1,10-phenanthroline) doped with Li at a molar ratio of 1:1. Other electron-transport materials can be used as long as the emissive properties of the phosphorescent materials are not adversely affected.

The charge carrying component of the electron-transport layer can be selected such that electrons can be efficiently injected from the cathode into the LUMO (Lowest Unoccupied Molecular Orbital) energy level of the electron-transport layer. The “charge carrying component” is the material responsible for the LUMO energy level that actually transports electrons. This component can be the host material, or it can be a dopant. The LUMO energy level of an organic material is generally characterized by the electron affinity of that material and the relative electron-injection efficiency of a cathode is generally characterized in terms of the work function of the cathode material. This means that the preferred properties of an electron-transport layer and the adjacent cathode are specified in terms of the electron affinity of the charge carrying component of the electron-transport layer and the work function of the cathode material. In particular, so as to achieve high electron-injection efficiency, the work function of the cathode material is preferably not greater than the electron affinity of the charge carrying component of the electron-transport layer by more than about 0.75 eV, more preferably, by not more than about 0.5 eV. Similar considerations apply to any layer into which electrons are being injected.

The cathode layer and the anode layer can comprise the same or different material, including but not limited to metal, alloy, transparent metal oxide, or mixtures thereof. In one embodiment, at least one of the cathode layer and the anode layer is transparent.

Anode materials for phosphorescent OLEDs typically include those having a high work function value. Non-limiting examples of anode materials include, but are not limited to, indium tin oxide (ITO), tin oxide, indium oxide, zinc oxide, indium zinc oxide, nickel, gold, and like materials and mixtures thereof

The cathode layer can be any material or combination of materials known to the art, such that cathode layer is capable of conducting electrons and injecting them into the emissive layers. Exemplary cathode materials typically include materials having low work function value. Non-limiting examples of cathode materials include materials such as K, Li, Na, Mg, Ca, Sr, Ba, Al, Ag, Au, In, Sn, Zn, Zr, Sc, Y, Mn, Pb, elements of the lanthanide series, alloys thereof, particularly Ag—Mg alloy, Al—Li alloy, In—Mg alloy, Al—Ca alloy, and Li—Al-alloy and mixtures thereof. Other examples of cathode materials may include alkali metal fluorides, or alkaline earth fluorides, or mixtures of fluorides. Other cathode materials such as indium tin oxide, tin oxide, indium oxide, zinc oxide, indium zinc oxide, zinc indium tin oxide, antimony oxide, carbon nanotubes, and mixtures thereof. Alternatively, the cathode may be made of two layers to enhance electron-injection Non-limiting examples include, but are not limited to, an inner layer of either LaF or NaF followed by an outer layer of aluminum or silver, or an inner layer of calcium followed by an outer layer of aluminum or silver.

The cathode layer can be transparent or opaque, and can be reflective. Metals and metal oxides are examples of suitable cathode materials. The cathode layer can be a single layer, or can have a compound structure comprising for example a thin metal layer and a thicker conductive metal oxide layer. In a compound cathode, preferred materials for the thicker layer include ITO, IZO, and other materials known to the art. An exemplary compound cathode comprises a thin layer of metal such as Mg:Ag with an overlying transparent, electrically-conductive, sputter-deposited ITO layer. The part of the cathode layer that is in contact with the underlying organic layer, whether it is a single layer cathode, the thin metal layer of a compound cathode, or some other part, is made of a material having a work function lower than about 4 eV (a “low work function material”). Other cathode materials and structures can be used.

Generally, injection layers comprise a material that can improve the injection of charge carriers from one layer, such as an electrode or an organic layer, into an adjacent organic layer. Injection layers can also perform a charge transport function. The hole-injection layer can be any layer that improves the injection of holes from the anode layer into either emissive layer or a hole-transport layer (not shown). CuPc is an example of a material that can be used for a hole-injection layer from an ITO anode and other anodes. Similarly, an electron-injection layer, for is any layer that improves the injection of electrons into either an electron-transport layer or emissive layer. LiF/Al is an example of a material that can be used as an electron-injection layer into an electron-transport layer from an adjacent layer, for example the cathode layer. Other materials or combinations of materials can be used for injection layers. Depending upon the configuration of a particular device, injection layers can be disposed at locations other than those shown in FIGS. 2-4. A hole-injection layer can comprise a solution deposited material, such as a spin-coated polymer, e.g., poly(3,4-ethylenedioxythiophene):polystyrene sulfonic acid (PEDOT:PSS), or it can be a vapor deposited small molecule material, e.g., copper phthalocyanine (CuPc) or 4,4′,4″-Tris(N-3-methylphenyl-N-phenyl- amino)-triphenylamine (MTDATA).

The hole-injection layer (HIL) can planarize or wet the anode surface so as to provide efficient hole-injection from the anode into the hole-injecting material. A hole-injection layer can also have a charge carrying component having HOMO (Highest Occupied Molecular Orbital) energy levels that favorably match up, as defined by their herein-described relative ionization potential (IP) energies, with the adjacent anode layer on one side of the HIL and the hole-transporting layer on the opposite side of the HIL. The “charge carrying component” is the material responsible for the HOMO energy level that actually transports holes. This component can be the host material of the HIL, or it can be a dopant. A doped HIL allows the dopant to be selected for its electrical properties, and the host to be selected for morphological properties such as wetting, flexibility, toughness, etc. Preferred properties for the HIL material are such that holes can be efficiently injected from the anode into the HIL material. In particular, the charge carrying component of the HIL preferably has an IP not more than about 0.7 eV greater that the IP of the anode material. More preferably, the charge carrying component has an IP not more than about 0.5 eV greater than the anode material. Similar considerations apply to any layer into which holes are being injected. HIL materials are further distinguished from conventional hole-transporting materials that are typically used in the hole-transporting layer of an OLED in that such HIL materials can have a hole conductivity that is substantially less than the hole conductivity of conventional hole-transporting materials. The thickness of the HIL can be thick enough to help planarize or wet the surface of the anode layer. For example, an HIL thickness of as little as about 10 nanometers can be acceptable for a very smooth anode surface. However, since anode surfaces tend to be very rough, a thickness for the HIL of up to about 50 nanometers is desired in some cases.

The phosphorescent OLED can further comprise a blocking layer. Blocking layers reduce the number of charge carriers (electrons or holes) and/or excitons that leave an emissive layer. An electron-blocking layer can be disposed between an emissive layer and a hole-transport layer, to block electrons from leaving the emissive layer in the direction of hole-transport layer. Similarly, a hole-blocking layer can be disposed between an emissive layer and an electron-transport layer, to block holes from leaving the emissive layer in the direction of the electron-transport layer. Blocking layers can also be used to block excitons from diffusing out of an emissive layer.

As used herein, and as would be understood by one skilled in the art, the term “blocking layer” means that the layer provides a barrier that significantly inhibits transport of charge carriers and/or excitons through the device, without suggesting that the layer necessarily completely blocks the charge carriers and/or excitons. The presence of such a blocking layer in a device can result in substantially higher efficiencies as compared to a similar device lacking a blocking layer. Also, a blocking layer can be used to confine emission to a desired region of an OLED.

A protective layer can be used to protect underlying layers during subsequent fabrication processes. For example, the processes used to fabricate metal or metal oxide top electrodes can damage organic layers, and a protective layer can be used to reduce or eliminate such damage. In particular, a protective layer has a high carrier mobility for the type of carrier that it transports, such that it does not significantly increase the operating voltage of OLED device. CuPc, 2,9-dimethyl-4,7-diphenyl-1,10-phenanthroline (BCP), and various metal phthalocyanines are examples of materials that can be used in protective layers. Other materials or combinations of materials can be used. The protective layer is generally of a thickness capable of preventing damage to underlying layers due to fabrication processes that occur after the organic protective layer is deposited, yet not so thick as to significantly increase the operating voltage of OLED device. The protective layer can be doped to increase its conductivity. For example, a CuPc or BCP protective layer can be doped with Li.

The emissive layers can have a thickness from about 0.01 micrometers to about 100 micrometers, more particularly about 0.02 micrometers to about 100 micrometers, even more particularly about 0.1 micrometers to about 10 micrometers and can comprise a host material and a phosphorescent material in a weight ratio ranging from 100:1 to 100:30. An emissive layer host material can comprise, for example, an asymmetric aluminum complex, such as bis(2-methyl-8-quinolinolato)(p-phenylphenolato)aluminum (Balq) or 8-(hydroxyquinoline)-4-(phenylphenol)aluminum, or carbazoles, such as 4,4′-N,N′-dicarbazole-biphenyl (CBP) or its derivatives. Without being bound by theory, the Highest Occupied Molecular Orbital (HOMO) of the phosphorescent material must be less than that of the host material, for example, 5.7 eV of Balq. This means that the hole mobility of the phosphorescent material is faster than that of the host material. Experiments show the triarylamine doped into the light emitting layer can reduce driving voltage.

Also contemplated are interlayers coated between the emissive layers of the phosphorescent OLED device, to inhibit intermixing of the organic layers.

Exemplary coating methods include, but are not limited to, spin coating, dip coating, reverse roll coating, wire-wound or Mayer rod coating, direct gravure coating, offset gravure coating, slot die coating, blade coating, hot melt coating, curtain coating, knife over roll coating, extrusion, air knife coating, spray, rotary screen coating, multilayer slide coating, meniscus coating, comma coating, microgravure coating, ink jet coating, and liquid electrophotographic coating.

Any solvent or solvent combination, including aqueous and organic solvents can be used to coat a mixture comprising emissive layer components, with the proviso that the adjacent previously coated emissive layer is not readily soluble in the solvent, and the emissive properties of the OLED device are not adversely affected. Particular solvents include hydrocarbons such as o-xylene, m-xylene, p-xylene, toluene, hexanes, like solvents, and combinations of two or more of the foregoing solvents. Other solvents include halogenated solvents, for example chlorobenzene. Still other solvents include water and/or alcohols such as methanol, ethanol, and 2-ethoxyethanol.

Other embodiments are contemplated for OLED devices having two phosphorescent emissive layers. In one embodiment, the first emissive layer and the second emissive layer comprise the same emissive chromophore in different chemical compositions that exhibit different solubility behavior. For example, the first emissive layer can comprise a copolymer HTM-CO-FIrpic derived from a hole-transporting host material (HTM) and a polymerizable monomer of FIrpic, and the second emissive layer can comprise an electron-transporting host material (ETM) and FIrpic in the form of a blend or a copolymer (ETM-CO-FIrpic). The first emissive layer has negligible solubility in the solvent used to coat the second emissive layer.

The first emissive and second emissive layers can comprise host materials and/or phosphorescent materials that are incompatible when mixed in a melt or in solution, forming films having multiple phases. In one embodiment, a host material of a first emissive layer and a phosphorescent polymer of a second emissive layer are incompatible in a melt or in solution, forming films having multiple phases. Emissive layers coated from such materials are characterized by well-defined recombination zones and high performance.

In a more specific embodiment, the phosphorescent OLED comprises a substrate comprising glass, an anode layer comprising indium tin oxide (ITO) disposed on the glass, a hole-injection layer comprising PEDOT:PSS disposed on the anode layer, a first emissive layer comprising a copolymer of a hole-transporting host material and a blue emitting phosphorescent dye (HTM-co-Blue) coated from chlorobenzene onto the hole injection layer, the second emissive layer comprises an electron-transporting host material and an orange emitting phosphorescent dye ADS078GE coated from toluene on the first emissive layer, and a cathode bi-layer comprising NaF layer disposed on the second emissive layer and an aluminum layer disposed on the NaF layer.

In a specific embodiment for a phosphorescent OLED comprising three emissive layers, the first emissive layer can comprise a copolymer of a hole-transporting host material and a blue emitting phosphorescent material (HTM-CO-Blue); the second emissive layer can comprise an electron-transporting host material and a green emitting phosphorescent material in the form of a copolymer (ETM-CO-Green) or a blend; and a third emissive layer can comprise an electron-transporting host material and a red emitting phosphorescent material in the form of a copolymer (ETM-CO-Red) or a blend. Even more specifically, the first phosphorescent material is blue emitting poly(carbazole_FIrpic), the first solvent is chlorobenzene, the second phosphorescent dye is green emitting poly(STPPB_IrPPy), the second solvent is 2-ethoxyethanol, the third phosphorescent dye is red emitting ADS067GE, the third solvent is toluene, the cathode layer comprises a NaF/Al bi-layer, and the anode layer comprises ITO. The above described embodiment produces a white light emitting OLED having high performance.

In one embodiment, the phosphorescent OLED comprises a first emissive layer comprising blue emitting phosphorescent polymeric dye 275-44-5, and a second emissive layer comprising orange phosphorescent dye ADS078GE. In one embodiment, the phosphorescent OLED further comprises a third organic phosphorescent emissive layer disposed on the second emissive layer; wherein the third emissive layer is not cured. In one embodiment, the phosphorescent OLED comprises a first emissive layer comprising blue emitting poly(carbazole_FIrpic), the second emissive layer comprises green emitting poly(STPPB_IrPPy, the third emissive layer comprises red emitting ADS067GE, the cathode layer is a bi-layer comprising NaF/Al, and the anode layer comprises ITO.

Also disclosed are articles comprising the disclosed OLED devices for lighting applications, including indoor lamps, outdoor lamps, ceiling lights, vehicle headlights, flashlights, and street lights.

The OLED devices can be activated by a signal (such as in a light emitting device) or a layer of material that responds to radiant energy and generates a signal with or without an applied potential (such as detectors or voltaic cells). Examples of electronic devices that can respond to radiant energy are selected from photoconductive cells, photoresistors, photoswitches, phototransistors, and phototubes, and photovoltaic cells. Those of ordinary skill will be capable of selecting material(s) that are suitable for their particular applications.

The following non-limiting example further illustrates the method of preparing a phosphorescent OLED device by coating each emissive layer sequentially from a solvent.

### EXAMPLE

A multi-layered phosphorescent OLED was constructed as follows. The phosphorescent OLED comprises a blue phosphorescent polymer emissive layer and a red phosphorescent emissive layer. Pre-patterned ITO coated glass was used as the anode substrate, and was cleaned with UV-ozone for 10 minutes. A layer (60 nm) of poly(3,4-ethylendioxythiophene) doped with polystyrene sulfonic acid (PEDOT:PSS) obtained from H.C. Starck was deposited atop the ITO via spin-coating and then baked for 1 hour at 180° C. in air. The coated substrate was then transferred into a glovebox filled with argon (both moisture and oxygen were less than 1 ppm). The blue phosphorescent polymer emissive layer of 275-44-5 (approximately 30 nm thickness) was then spin-coated from solution in chlorobenzene atop the PEDOT:PSS layer and baked on a hotplate (pre-heated to 120° C.) for 10 minutes. Next, a mixture of OXD-7 (1,3-bis[(p-tert-butyl)phenyl-1,3,4-oxadiazoyl]benzene), purchased from H.W. Sands and used as received, and ADS069RE in a ratio of OXD-7:ADS069RE of 90:10 by weight was spin-cast atop the blue emissive layer from its solution in toluene to form a red emissive layer (approximately 10 nm thickness). Finally, a bilayer cathode comprising NaF (4 nm thickness)/Al(1000 nm thickness) was thermally evaporated on top of the red emissive layer under a base vacuum of 2.67×10⁻⁴ Pa (2×10⁻⁶ Torr). After metallization, the device was encapsulated with a cover glass sealed with an optical adhesive Norland 68 obtained from Norland products, Inc, Cranbury, N.J. 08512, USA. The active area is about 0.2 cm².

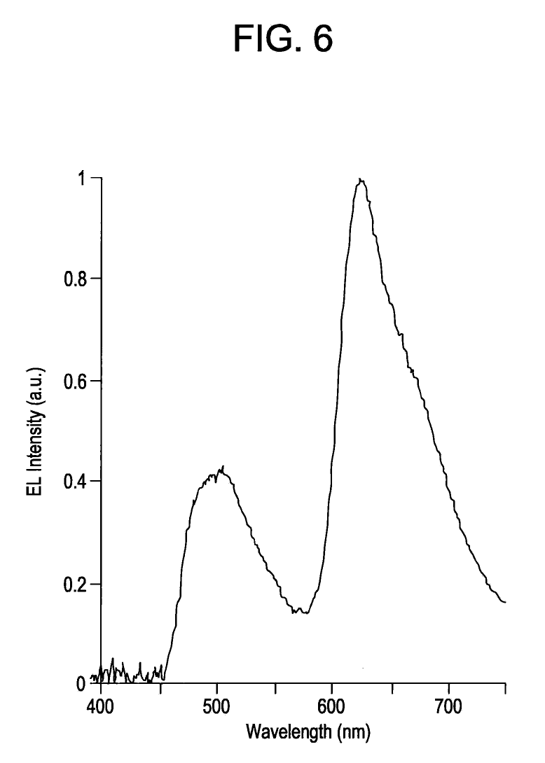

FIG. 6 shows the electroluminescence spectrum of the device having a blue component peaking at approximately 495 nm, characteristic to the emission of 277-44-5, and a red component peaking at 628 nm, characteristic to the emission of ADS069RE.

The singular forms “a,” “an,” and “the” include plural referents unless the context clearly dictates otherwise. All amounts, parts, ratios and percentages used herein are by weight unless otherwise specified. The endpoints of all ranges directed to the same characteristic or component are independently combinable and inclusive of the recited endpoint.

While the invention has been described with reference to the embodiments thereof, it will be understood by those skilled in the art that various changes can be made and equivalents can be substituted for elements thereof without departing from the scope of the invention. In addition, many modifications can be made to adapt a particular situation or material to the teachings of the invention without departing from the essential scope thereof. Therefore, it is intended that the invention not be limited to the particular embodiments disclosed as the best mode contemplated for carrying out this invention, but that the invention will include all embodiments falling within the scope of the appended claims.

What is claimed is:

1. A method for forming multi-emissive phosphorescent layers for a phosphorescent OLED, comprising:
coating a first phosphorescent material from a first solvent onto a first electrode and removing the first solvent to form a first emissive layer; and
coating a second phosphorescent material from a second solvent onto the first emissive layer and removing the second solvent to form a second emissive layer, wherein the first and second emissive layers are not cured after coating, and wherein the first emissive layer has negligible solubility in the second solvent.

2. The method of claim 1, further comprising coating from a solvent a hole-injection layer comprising poly(3,4-ethylendioxythiophene) doped with polystyrene sulfonic acid (PEDOT:PSS) between the first electrode and the first emissive layer.

3. The method of claim 1, further comprising coating an interlayer of electroactive material between the first and second emissive layers.

4. The method of claim 1, wherein the first emissive layer comprises a blue emitting phosphorescent polymeric dye 275-44-5, the first solvent is chlorobenzene, the second emissive layer comprises an orange phosphorescent dye ADS078GE, and the second solvent is toluene.

5. The method of claim 1, further comprising coating a third phosphorescent material from a third solvent onto the second emissive layer and removing the third solvent to form a third emissive layer; wherein the second phosphorescent material and the first phosphorescent material have negligible solubility in the third solvent, and the third emissive layer is not cured after coating.

6. The method of claim 5, further comprising depositing a second electrode onto the third emissive layer, wherein the first phosphorescent material is blue emitting poly(carbazole_FIrpic), the first solvent is chlorobenzene, the second phosphorescent material is green emitting poly(STPPB_IrPPy), the second solvent is 2-ethoxyethanol, the third phosphorescent material is red emitting ADS067GE, the third solvent is toluene, the second electrode comprises NaF/Al, and the first electrode comprises ITO.

7. A multi-emissive phosphorescent OLED device formed by the method of claim 1.

8. A multi-emissive phosphorescent OLED device, comprising:
a substrate;
an anode layer disposed on the substrate;
a first emissive layer disposed on the anode layer, wherein the first emissive layer comprises a first polymeric phosphorescent material;
a second emissive layer disposed on the first emissive layer, wherein the second emissive layer comprises a second phosphorescent material, wherein the first and second emissive layers are not cured; and
a cathode layer disposed on the second emissive layer.

9. The phosphorescent OLED device of claim 8, further comprising a hole-injection layer, a hole-transporting layer, a hole-blocking layer, an electron-injection layer, an electron-transporting layer, an electron-blocking layer, or a combination thereof.

10. The phosphorescent OLED device of claim 8, wherein the first and/or the second emissive layer comprises a mixture of phosphorescent materials.

11. The phosphorescent OLED device of claim 8, wherein the first emissive layer comprises a toluene insoluble blue phosphorescent polymeric dye 275-44-5, and the second emissive layer comprises a toluene soluble orange phosphorescent dye, ADS069RE.

12. The phosphorescent OLED device of claim 8 wherein the first emissive layer comprises a copolymer of a hole-transporting host material and a blue phosphorescent polymeric dye 275-44-5, and the second emissive layer comprises a blend or a copolymer of an electron-transporting host material and an orange emitting phosphorescent dye.

13. The phosphorescent OLED of claim 8, further comprising a hole-injection layer comprises poly(3,4-ethylendioxythiophene) doped with polystyrene sulfonic acid (PEDOT:PSS).

14. The phosphorescent OLED device of claim 8, wherein the second emissive layer further comprises an electron-transporting host material.

15. The phosphorescent OLED device of claim 8, wherein the first emissive layer further comprises a hole-transporting host material.

16. The phosphorescent OLED device of claim 8, wherein the second phosphorescent material is covalently bound to an electron-transporting polymeric host material.

17. The phosphorescent OLED device of claim 8, wherein the OLED device emits white light.

18. The phosphorescent OLED device of claim 8, further comprising a third emissive layer formed by coating a third mixture comprising a third phosphorescent material and a third solvent on the second emissive layer, and removing the solvent to form the third emissive layer, wherein the first and second emissive layers have negligible solubility in the third solvent, and the third emissive layer is not cured after coating.

19. An article comprising the multi-emissive phosphorescent OLED device of claim 8, wherein the article is for a lighting application.

20. The article of claim 19, wherein the article is an indoor lamp, outdoor lamp, ceiling light, vehicle headlight, flashlight, or street light.
